(19) United States
(12) Patent Application Publication
(10) Pub. No.: US 2009/0283305 A1
(43) Pub. Date: Nov. 19, 2009

(54) TIN-SILVER COMPOUND COATING ON PRINTED CIRCUIT BOARDS

(75) Inventors: Joseph J. Lynch, East Northport, NY (US); Richard Schneider, Livonia, MI (US)

Correspondence Address: DARBY & DARBY P.C., P.O. BOX 770, Church Street Station, New York, NY, 10008-0770, US

(73) Assignee: Interplex Industries, Inc., College Point, NY (US)

(21) Appl. No.: 12/466,099

(22) Filed: May 14, 2009

Related U.S. Application Data
(60) Provisional application No. 61/053,514, filed on May 15, 2008.

(51) Int. Cl. H05K 1/09; B05D 5/12; H05K 3/00

(52) U.S. Cl. 174/257; 427/97.1; 427/96.6

(57) ABSTRACT

A tin-silver coating for use with circuit boards, which can include a conductive circuit with an exposed surface disposed on a substrate. The tin-silver coating covers the exposed surface of the conductive circuit. The conductive circuit can include electrical traces, contact pads and vias, each of which may include or be formed of copper. In one embodiment, the tin-silver coating can include a tin weight percentage between 85 and 99.5%, while the silver weight percentage can be between 0.5 and 15%. In one embodiment the tin-silver coating can be between 35 and 60 millionths of an inch. A barrier plate may also be included between the conductive circuit and the tin-silver coating.

### CROSS REFERENCE TO RELATED APPLICATIONS

The present application claims the benefit of U.S. Provisional Patent Application Ser. No. 61/053,514, filed on May 15, 2008, the contents of which are hereby incorporated by reference in its entirety.

### FIELD OF THE INVENTION

The present invention generally relates to printed circuit boards, and more specifically to a coating for circuit boards

### BACKGROUND OF THE INVENTION

Printed circuit boards include traces of a highly conductive material, such as copper, disposed on the surface of a laminate to electrically connect electronic components. Copper, however has a relatively high melting point, and thus is difficult to connect with other electrical components directly. Additionally, copper oxidizes quickly and the connection can fail if the oxygen is left exposed to air. Accordingly, the exposed conductive portions on the circuit board, e.g., traces, along with the contact pads and vias of a circuit board, are typically covered with a conductive solderable coating. The conductive solderable coating is used to bond the contact pad to a lead of the electronic component.

Conventionally, tin-lead compounds have been used to create the solderable coating material. Tin-lead compounds are advantageous because they have a melting temperature which can be adjusted by varying the relative amounts of tin and lead in the compound. For example, a tin-lead compound having 63% tin and 37% lead is eutectic, meaning that it has the lowest possible melting point for the mixture of the two components, melting at 183° C. By varying the relative amounts of lead and tin, the melt temperature could be raised to a higher melting temperature as needed by the application. Nevertheless, despite this versatility, a call for a cleaner environment has led to the elimination of the use of lead as a doping agent. Consequently, the electronics industry has been replacing tin-lead compounds in component coatings and soldering materials with other alternative replacements.

Several materials have been used for printed circuit board (PCB) coatings as a replacement to tin-lead compounds. These include gold, tin, silver and/or silver combined with a tarnish inhibitor. The coatings can be applied to the conductive surfaces on the circuit board by electroplating, electroless plating or an immersion process. In the immersion process the copper atoms near the surface are replaced by atoms of the coating material. However, each of these material coatings has disadvantages. Gold is too costly to consider as a practical alternative to tin-lead. Although, a better value, tin coatings have a tendency to produce whisker growth. Tin whiskers are electrically conductive structures of tin that grow from the surface of the pure tin coating due to mechanical stress. These thin strands of tin have been observed to grow to lengths up to 10 mm. Thus, a PCB having closely spaced circuit elements or traces with a pure tin coating is susceptible to short circuit failure caused by tin whiskers bridging gaps between electrical components. Silver also has a number of disadvantages. First, the cost of silver is significantly higher than the tin-lead compounds it is being used to replace. Second, the silver coating typically needs a tarnish inhibitor to prevent tarnishing. Third, pure silver coatings are susceptible to dendrites, crystalline structures that grow from the surface and, which similar to tin whiskers, may cause short circuit failure. Lastly, pure silver is also susceptible to electromigration—a phenomenon in which the gradual movement of the ions in a conductor due to the momentum transfer between conducting electrons and diffusing metal atoms causes transport of the silver material. Although this effect is usually negligible, the high direct current densities used in circuit boards and the small cross section of the silver coating can result in gaps being formed in the surface coating over time.

Accordingly, there is a need for a coating for printed circuit boards that is inexpensive, is not highly susceptible to whisker growth, dendrite growth or electromigration, and does not require a tarnish inhibitor.

### SUMMARY OF THE INVENTION

The present invention in one embodiment is directed to a coating for circuit boards that is made of a tin-silver compound. In one embodiment, a printed circuit board or a printed circuit card includes a conductive circuit with an exposed surface disposed on a substrate. A tin-silver coating covers the exposed surface of the conductive circuit. The conductive circuit can include electrical traces, contact pads and vias, each of which may include or be formed of copper. In a specific embodiment, the tin-silver coating can include a tin weight percentage between 85 and 99.5, while the silver weight percentage can be between 0.5 and 15%. In one embodiment the tin-silver coating can be between 5 and 60 millionths of an inch. A barrier plate may also be included between the conductive circuit and the tin-silver coating.

The tin-silver compound is provided as a coating to prevent the formation of silver dendrites or tin whiskers which appear most frequently in pure tin coated electrical components under mechanical stress. The relative proportion of tin and silver may be modified to thereby modify the temperature characteristics, such as melt temperature, to suit particular applications.

### BRIEF DESCRIPTION OF THE DRAWINGS

The foregoing and other features of the present invention will be more readily apparent from the following detailed description and drawings of illustrative embodiments of the invention in which:

FIG. 1 is a cross section of an embodiment of a PCB with a tin-silver coating in accordance with the present invention; and

FIG. 2 is a cross section of another embodiment of a PCB with a tin-silver coating in accordance with the present invention.

### DETAILED DESCRIPTION OF THE PREFERRED EMBODIMENTS

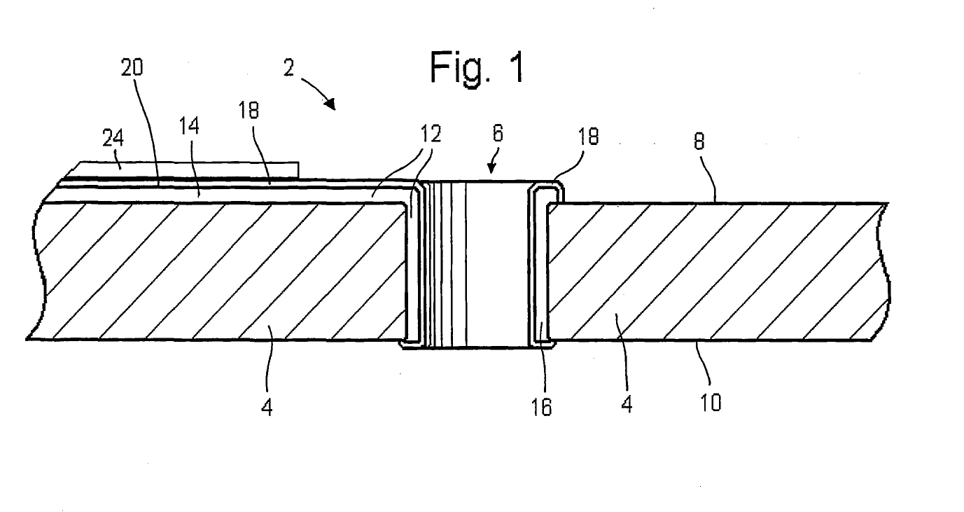

FIG. 1 shows a cross section of a portion of a printed circuit board 2 in accordance with the present invention. The PCB 2 includes a substrate 4 which may, for example, be a laminate 4. The laminate 4 can, for example, be formed of any of glass epoxy, polyimide, ceramic and an Insulated Metal Substrate. The Insulated Metal Substrate could have a conductive base layer such as, for example, aluminum or copper, with an electrical insulator disposed on a surface of the base layer. The shown laminate 4 includes a via 6 that extends from a top surface 8 of the fiberglass laminate 4 to a bottom surface 10 of the laminate 4. A conductive circuit 12 is disposed on the non-conductive substrate 4 and provides a connection between electronic components that may be attached to the PCB. The circuit 12 is formed of a conductive material that is disposed on a surface of the laminate 4, which, for example may be a copper trace 14, which is shown in FIG. 1. At opposing ends of the connection, the circuit can connect to an electronic component or can pass through a via 6 to the bottom side of the non-conductive substrate 4. The via 6 provides an electrical connection therethrough by having a conductive layer 16 around its outer surface that is part of the conductive circuit 12. If the PCB is a multi-layer board, the via 6 may connect components on the top surface 8 of the laminate 4 to components on the bottom surface 10, or to inner layers of the PCB. The via 6 can also be used as a connection point to an electrical component by inserting a lead of the electrical component into the via 6 and soldering the lead to the conductive layer 16 on the surface of the via 6, or by inserting a solderless connection into the via. The conductive layer 16 may also be formed of copper or another conductive material.

The conductive circuit 12 can be placed on the laminate 4 by a variety of known methods. In an exemplary embodiment, the non-conductive substrate 4 includes a conductive layer bonded to its entire top surface 8 and possibly also its bottom surface 10. In the described embodiment, the conductive layer is made of copper. Unnecessary portions of the copper layer are then etched away leaving a pattern that provides the conductive circuit 12. Any vias in the PCB may then be drilled through the laminate 4 and the remaining conductive circuit pattern. The walls of the via 6 can then be plated with a conductive material, such as copper, to provide the conductive layer 16 on the outer surface of the via 6 as shown in FIG. 1. In an alternative method, the conductive circuit can be disposed on the non-conductive substrate by an additive process, for example, by a multi-stepped plating process.

Covering the exposed surfaces 20 of the remaining conductive circuit 12 is a coating 18 made of a tin-silver compound. The tin-silver coating can be applied over the conductive circuit by electroless plating or an immersion process. Electroless plating is a known chemical process in which the plated atoms are adhered to the desired surface. The immersion process is also chemical, but in contrast, atoms on the surface of the underlayer, in this case the conductive circuit 12, are replaced by the applied material. In one embodiment, the tin-silver compound is made up of between 85 and 99.5 weight of tin and between 0.5 and 15% weight of silver and is applied at a thickness range between 5 and 60 microinches. The relative proportion of tin and silver may be modified to thereby modify the temperature characteristics, such as melt temperature, to Suit particular applications.

Tin-silver coatings are described in U.S. Pat. Nos. 6,924,044 and 7,147,933, which are incorporated herein by reference. Other materials or doping agents, such as bismuth, silicon, magnesium, iron, manganese, zinc or antimony, may be added to the compound as desired to contribute properties, such as hardness, as required by a particular application. If one or more such additions are added to the compound, these additions will preferably make up less than 10% weight of the compound.

The tin-silver coating is advantageous compared to pure tin or pure silver coatings. In comparison to pure tin coatings, the tin-silver coating does not produce whiskers which may lead to short circuit failure. In comparison to pure silver coatings, the tin-silver coating is less expensive, has much lower electromigration and does not produce dendrites which may result in short circuit failure. Further, the tin-silver coating does not require a tarnish inhibitor, which would otherwise be required with a pure silver coating. Nor is an organic solder preservant necessary which would otherwise be needed for an exposed copper layer.

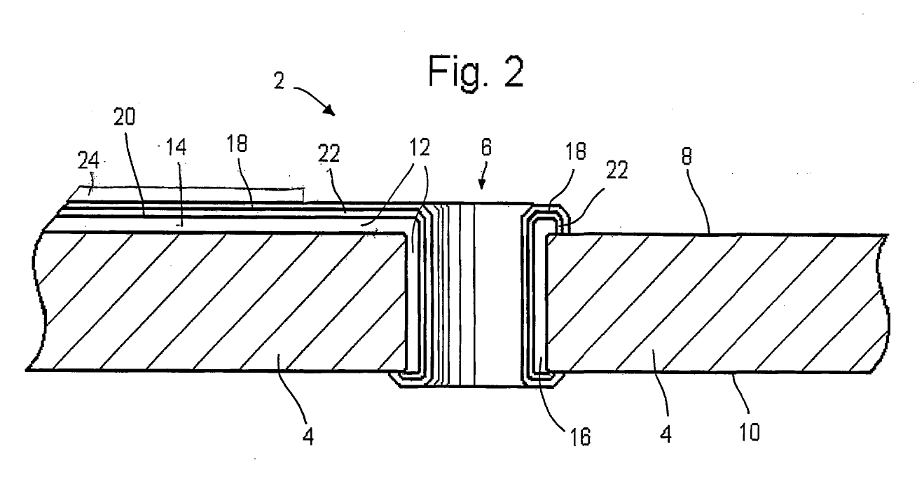

In the embodiment shown in FIG. 1, the tin-silver coating 18 is applied directly on the conductive circuit 12, such that the underlying copper traces 14 are adjacent the tin-silver coating 18. In an alternative embodiment, such as that shown in FIG. 2, a barrier plate 22 may be disposed between the conductive circuit 12 and the tin-silver coating 18. The barrier plate 22 can be formed of any of a variety of materials, including nickel or copper. The barrier plate 22 can be disposed on the exposed surface 20 and the tin-silver coating 18 can be applied to the barrier plate by electroless plating or the immersion process, as described above. The barrier plate layer 22 can have a thickness in a range between 100 and 200 microinches. With a barrier plate layer in this thickness range, the tin-silver coating may have a thickness in a range of 5 to 8 microinches.

Once the tin-silver coating 18 is applied to cover the conductive circuit, including any traces 14, vias 6 and contact pads therein, a solder mask 24 may be applied on top of the conductive coating 18, as shown in FIGS. 1 and 2. The solder mask may be green as is typical. Solder paste may then be applied to the circuit board, particularly in areas where there is the tin-silver coating 18, or solder. The solder paste may be applied by silk screening. The solder paste does not adhere to the mask and thus, the solder mask helps prevent the tin-silver coating 18 or solder paste from bridging between traces 14 or other portions of the electronic circuit. Silk screening can also be used to apply a non-conductive coating 24 to areas of the conductive tin-silver coating which do not need to be exposed. Alternatively, solder paste or solder can be applied on top of the coating using solder slugs or bricks.

While the invention has been particularly shown and described with reference to preferred embodiments thereof, it will be understood by those skilled in the art that various changes in form and details may be made therein without departing from the spirit and scope of the invention.

We claim:

1. An electrical device with a tin-silver coating comprising:
a substrate including a non-conductive first surface;
a conductive circuit disposed on the first surface of the substrate, the conductive circuit including an exposed surface;
a coating comprising a tin-silver compound disposed over the exposed surface of the conductive circuit.

2. The electrical device of claim 1, wherein the substrate and conductive circuit form a printed circuit board.

3. The electrical device of claim 2, wherein the conductive circuit includes at least one copper trace.

4. The electrical device of claim 1, wherein the coating includes a tin weight percentage between 85% and 99.5%.

5. The electrical device of claim 1, wherein the coating includes a silver weight percentage between 0.5% and 15%.

6. The electrical device of claim 1, wherein the substrate includes a via extending from the first surface to a second surface opposite the first surface, a surface of the via includes a conductive material disposed thereon, and the coating is disposed over the conductive material.

7. The electrical device of claim 1, further comprising a barrier plate disposed between the conductive circuit and the coating.

8. The electrical device of claim 1, wherein the coating includes at least one doping agent selected from the group containing bismuth, silicon, magnesium, iron, manganese, zinc and antimony.

9. A method of making an electrical device comprising:
providing a substrate with a non-conductive first surface;
disposing a conductive circuit on the first surface of the substrate, the conductive circuit including an exposed surface; and
disposing a coating comprising a tin-silver compound over the exposed surface of the conductive circuit.

10. The method of claim 9, wherein the step of disposing the conductive circuit on the first surface of the substrate includes a step of etching a conductive layer on the first surface of the substrate so as to form the conductive circuit.

11. The method of claim 9, wherein the coating includes a tin weight percentage between 85% and 99.5%.

12. The method of claim 9, wherein the coating includes a silver weight percentage between 0.5% and 15%.

13. The method of claim 9, further comprising the step of disposing a barrier plate on the exposed surface of the conductive circuit before disposing the coating over the exposed surface of the conductive circuit.

14. The method of claim 9, further comprising the steps of providing a via in the substrate extending from the first surface to a second surface opposite the first surface, disposing a conductive material on a surface of the via, and disposing the coating on the conductive material.

15. The method of claim 9, further comprising the step of disposing a solder mask on a portion of the coated conductive circuit.

16. The method of claim 9, further comprising the step of disposing solder paste on a portion of the coated conductive circuit

17. A method of mitigating whisker formation resulting from mechanical stress, the method comprising:
disposing a coating comprising a tin-silver compound over an exposed surface of a conductive circuit on a substrate such that whisker formation is mitigated when the substrate is subjected to mechanical stress.

18. The method of claim 17, wherein the coating includes a tin weight percentage between 85% and 99.5%.

19. The method of claim 17, wherein the coating includes a silver weight percentage between 0.5% and 15%.
